(19) United States
(12) Patent Application Publication
(10) Pub. No.: US 2006/0018093 A1
(43) Pub. Date: Jan. 26, 2006

(54) Closed-loop cycling type heat-dissipation apparatus

(75) Inventors: Chyi-Lang Lai, Chiayi County (TW); Tsung-Wen Huang, Tainan City (TW)

Correspondence Address: BACON & THOMAS, PLLC, 625 SLATERS LANE, FOURTH FLOOR, ALEXANDRIA, VA, 22314, US

(73) Assignee: Metal Industries Research & Development Centre, Kaohsiung City (TW)

(21) Appl. No.: 11/105,424

(22) Filed: Apr. 14, 2005

(30) Foreign Application Priority Data
Jul. 21, 2004 (TW) 93121717

(51) Int. Cl. H05K 7/20

(52) U.S. Cl. 361/689

(57) ABSTRACT

This invention provides a closed-loop cycling type heat-dissipation apparatus, including at least one metal conduit and plural heat-dissipation fins. Hot air in a housing of a screen module is channeled into the metal conduit through an upper exit of the housing. Heat-dissipation fins attached onto the metal conduit then make heat exchange with atmosphere. The heat of the hot air is dissipated to atmosphere by thermal convection or thermal radiation of surfaces of the heat-dissipation fins. The hot air is cooled down and then channeled into the housing of the screen module through a lower entrance thereof. A closed-loop heat-dissipation cycle is formed. Inner temperature of the housing and temperature difference between inner part and outer part of the housing are effectively lowered. The present apparatus can provide a capability sufficient for heat-dissipation while without the aid of other baggage. The heat-dissipation is relied on nature heat-dissipation cycle in a system and without thermal convection between air in the system and atmosphere.

### BACKGROUND OF THE INVENTION

1. Field of the Invention

The present invention relates to a heat-dissipation apparatus, and more particularly to a closed-loop cycling type heat-dissipation apparatus, which can dissipate heat carried with hot air in a system by a nature heat-dissipation cycle.

2. Description of the Related Art

As increasing advancement of IC (Integrated Circuit) technology, electronic industry is rapidly and persistently developed. It is a trend for electronic devices toward high density and high speed, which causes a problem of heat-dissipation. The demands of display quality, contrast, resolution and size of the display are persistently increased with integration density of display becoming higher and higher. Heat generated by the display is also increased. However, when the heat is not dissipated on time, inner temperature of the display would rapidly rise, which largely and negatively affects display stability and operation life of the display.

Nowadays, new display design is continuously created. Heat quantity generated there from is larger and larger. Heat dissipation merely relied on the electronic device itself cannot satisfy the need any more. In general, a heat-dissipation apparatus is disposed on a surface of the display to aid for heat-dissipation. However, as the demand of heat-dissipation is increased more and more, technologies of the heat-dissipation apparatus are also rapidly developed.

In order to obtain higher heat-dissipation performance, heat-dissipation fins had better be made laminate and high density. Thermal-tube heat-dissipation device is another heat-dissipation apparatus. The thermal-tube heat-dissipation device is vertically positioned on a substrate, and a plurality of heat-dissipation fins are parallely fastened on the thermal tube in an equal-spaced manner. The thermal tube contains a working fluid with stable chemical properties and easily phase change. One end of the thermal tube contacts a heat source, and the heat from the heat source is transported to the other end of the thermal tube by cycling of the working fluid in the thermal tube, and the heat is dissipated.

The above two heat-dissipation implements merely dissipate local heat of the screen module, and cannot effectively lower heat from inner heat sources of the screen module. Therefore, unbalance of inner temperature and outer temperature of the screen module cannot be resolved. In other words, the outer temperature of the screen module can be lowered by the aid of the heat-dissipation fins or the thermal tube. While the inner temperature of the screen module arising from the heat sources cannot be lowered due to lack of heat-dissipation apparatus for them.

Accordingly, the drawback of unbalance of the inner temperature and outer temperature of the screen module needs to be overcome.

### SUMMARY OF THE INVENTION

It is one objective of the present invention to provide a closed-loop cycling type heat-dissipation apparatus applied to a liquid crystal display module or a lamp tube module, which can channel out hot air in a housing having a plurality of lamp tubes provided therein, by the present invention a closed-loop cycling type heat-dissipation path is formed by nature heat-dissipation cycle of hot air in the housing and cooled air outside the housing.

It is another objective of the present invention to provide a closed-loop cycling type heat-dissipation apparatus, which utilizes a metal conduit to communicate with an upper hole and a lower hole of a housing to form a closed-loop cycling type heat-dissipation path around the housing. A plurality of heat-dissipation fins is disposed on an outer surface of the metal conduit to improve heat-exchange efficiency so as to effectively lower inner temperature of the housing and difference between inner temperature and outer temperature of the housing.

In order to attain the above objectives, the present invention provides a closed-loop cycling type heat-dissipation apparatus, including at least one metal conduit and a plurality of heat-dissipation fins. Two ends of the metal conduit are respectively communicated with an upper hole and a lower hole of a housing to form a closed-loop heat-dissipation cycle. A plurality of heat-dissipation fins is attached onto the metal conduit.

It is preferable that a plurality of heat-dissipation fins is disposed on an outer surface of the housing.

It is preferable that a liquid crystal display module or other lamp tube module is provided in the housing.

It is preferable that the heat-dissipation fins are arranged along radial directions or circumferential directions of the metal conduit, and also can be disposed at other portions of the housing, such as a backside of the housing.

It is preferable that a portion of the metal conduit respectively communicating with an exit and an entrance of the housing can be made of polymer material or other thermal insulating material to avoid reversed thermal diffusion.

It is preferable that a fan is disposed at surrounding of the housing.

### BRIEF DESCRIPTION OF THE DRAWINGS

These and other features, aspects and advantages of the present invention will be better understood with regard to the following description, appended claims and accompanying drawings that are provided only for further elaborateness without limiting or restricting the present invention, where:

FIG. 1 is a schematic view of a structure of a screen module according to a preferred embodiment of the present invention; and

FIG. 2 is a schematic view of a structure of a screen module according to another preferred embodiment.

### DETAILED DESCRIPTION OF THE PREFERRED EMBODIMENTS

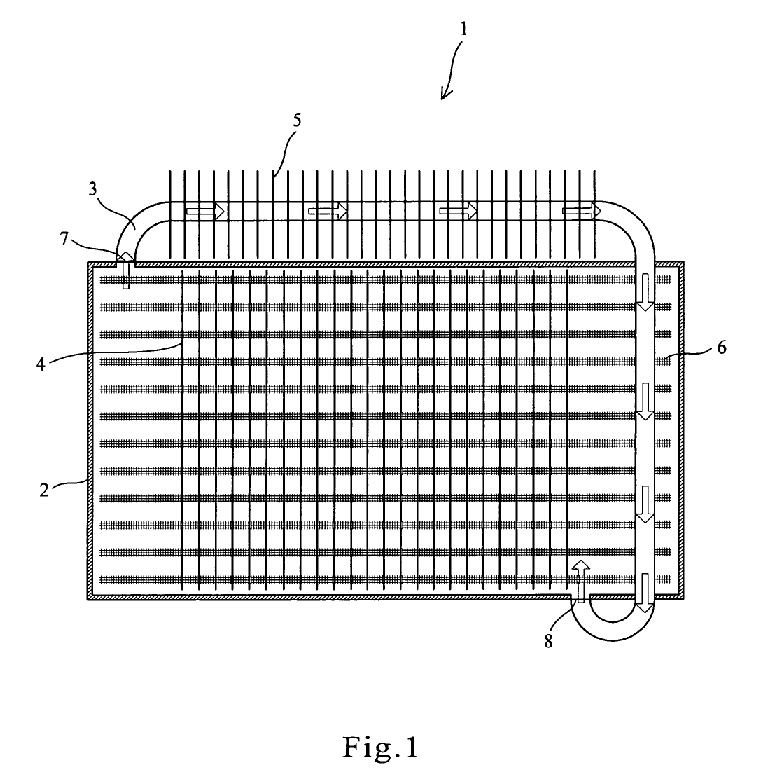

Firstly, referring to FIG. 1, which shows a schematic view of a structure of a screen module 1 according to one preferred embodiment of the present invention. In this preferred embodiment, a metal conduit 3 surrounds one side of a housing 2, with one end of the metal conduit 3 communicating with an upper exit 7 of the housing 2 and the other end of the metal conduit 3 communicating with a lower entrance 8 of the housing 2. A plurality of heat-dissipation fins 4 is arranged at a backside of the housing 2, and a plurality of heat-dissipation fins 5 is attached unto the metal conduit 3 and arranged in an equal-spaced manner along radial directions of the metal conduit 3.

Heat from the housing itself 2 is dissipated by the heat-dissipation fins 4 disposed at the backside of the housing 2, and hot air from the inner part of the housing 2 is channeled out through the metal conduit 3 communicating with the upper exit 7 of the housing 2. The hot air flows along an arrow direction in the metal conduit 3, and heat carried with the hot air is dissipated to atmosphere by thermal convection or thermal radiation of outer surfaces of the heat-dissipation fins 5 such that the hot air in the metal conduit 3 is cooled down and then channeled back to the housing 2 through the lower entrance 8 of the housing 2 to form a closed-loop heat-dissipation cycle. Inner temperature of the housing 2 and difference between inner temperature and outer temperature of the housing 2 are lowered.

By the way, the screen module 1 can be a liquid crystal display, plasma display and flat display of a computer.

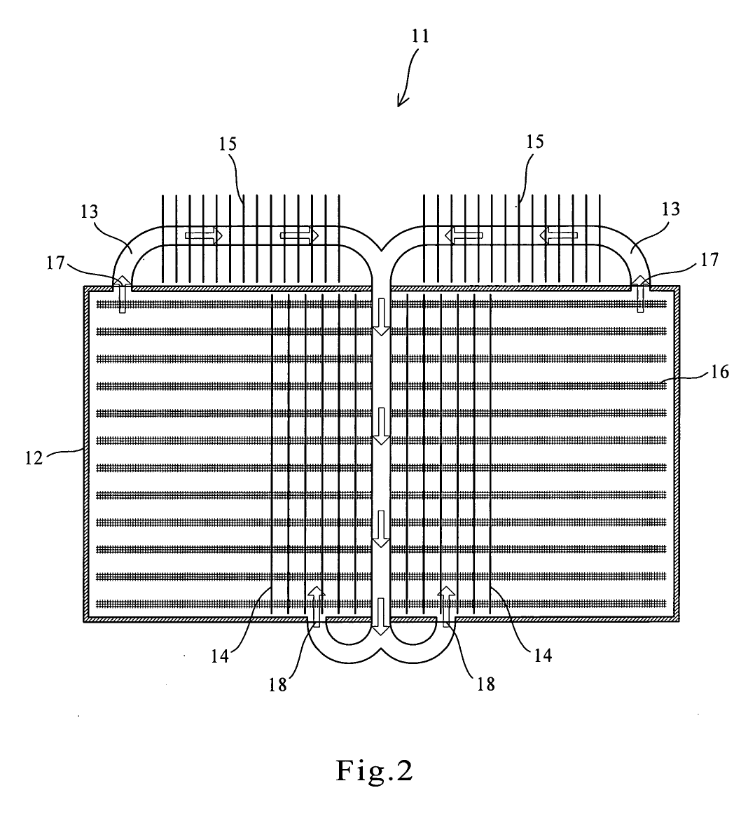

Please refer to FIG. 2, which shows a schematic view of a structure of a screen module 11 according to another preferred embodiment of the present invention. In this preferred embodiment, two metal conduits 13 share a common conduit body outside the middle area of the housing 12 and with their one end respectively communicating with a left upper exit 17 and a right upper exit 17 of the housing 12. The other end of each of the two metal conduits 13 respectively communicates with one of two lower entrances 18 of the housing 12. A plurality of heat-dissipation fins 15 is attached unto the metal conduits 13 and arranged in an equal-spaced manner along radial directions of the metal conduits 13.

Heat from the housing itself 12 is dissipated by the heat-dissipation fins 14 disposed at the backside of the housing 12, and hot air from inner part of the housing 12 is channeled out through the two metal conduits 13 communicating with the two upper exits 17 of the housing 12. The hot air flows along an arrow direction in the metal conduits 13, and heat carried with the hot air is dissipated to atmosphere by thermal convection or thermal radiation of outer surfaces of the heat-dissipation fins 15, such that the hot air in the metal conduits 13 is cooled down and channeled back into the housing 12 through the lower entrances 18 of the housing 12 to form two closed-loop heat-dissipation cycles. Inner temperature of the housing 12 and difference between inner temperature and outer temperature of the housing 12 are lowered.

Besides, the screen module 11 can be a liquid crystal display, plasma display and flat display of a computer.

The present apparatus provides following advantages: employing nature thermal convection of an inner part of the screen module and a closed-loop cycling type heat-dissipation apparatus without other baggage such as another power device or component, which can effectively reduce cost of the screen module, system noise and difficulty of manufacture and assembly, and lowering inner temperature of the system, as well as lengthening operation life of the screen module; the closed-loop design can avoid contamination of the inner part of the housing arising from air convection between the inner part of the housing and atmosphere, that would damage the screen module or cause adverse influence; except for improving heat-dissipation capability of the screen module, a larger-sized screen module also becomes possible.

Although the present invention has been described in considerable detail with reference to certain preferred embodiments thereof, those skilled in the art can easily understand that all kinds of alterations and changes can be made within the spirit and scope of the appended claims. Therefore, the spirit and scope of the appended claims should not be limited to the description of the preferred embodiments contained herein.

What is claimed is:

1. A closed-loop cycling type heat-dissipation apparatus, including:
at least one metal conduit with one end communicating with an upper hole of a housing and the other end communicating with a lower hole of said housing to form a closed-loop heat dissipation cycle; and
a plurality of heat-dissipation fins attached onto said metal conduit.

2. The apparatus of claim 1, wherein said housing has a liquid crystal display module and a lamp tube module disposed therein.

3. The apparatus of claim 1, wherein said upper hole of said housing is used as an air exit and said lower hole is used as an air entrance.

4. The apparatus of claim 3, wherein said housing has two exits and two entrances, and one end of each of said two metal conduits communicates with one said exit and the other end of each of said two metal conduit communicates with one said entrance.

5. The apparatus of claim 3, wherein air in said housing is channeled into said metal conduit through said air exit, and air passing said metal conduit is then channeled back into said housing through said air entrance.

6. The apparatus of claim 1, wherein said heat-dissipation fins are arranged along radial directions of said metal conduit or circumferential directions thereof.

7. The apparatus of claim 3, wherein a portion of said metal conduit respectively connected to said air exit and said air entrance of said housing is made of polymer material or other thermal insulating material to avoid reversed thermal diffusion.

8. The apparatus of claim 1, wherein the closed-loop heat-dissipation cycle is realized by using said metal conduit to transport the air from said housing and dissipate heat carried with the air while without thermal convection between the air within said housing and atmosphere.

9. The apparatus of claim 1, wherein a fan is disposed at surrounding of said housing.

10. The apparatus of claim 1, wherein an outer surface of said housing is provided with a plurality of heat-dissipation fins.

11. A screen module, including:
a housing with plural heat bodies provided therein, said housing having at least an exit and an entrance;
at least one metal conduit for communicating with said exit and said entrance of said housing to form a closed-loop heat-dissipation cycle; and
a plurality of heat-dissipation fins attached onto said metal conduit.

12. The screen module of claim 11, wherein said screen module is selected from the following: liquid crystal display, plasma display and flat display of a computer.

13. The screen module of claim 11, wherein said housing has two exits and two entrances, and one end of each of said two metal conduits communicates with one said exit and the other end of each of said two metal conduit communicates with one said entrance.

14. The screen module of claim 11, wherein air in said housing is channeled into said metal conduit through said exit, and air passing said metal conduit is then channeled back into said housing through said entrance.

15. The screen module of claim 11, wherein said heat-dissipation fins are arranged along radial directions of said metal conduit or circumferential directions thereof.

16. The screen module of claim 11, wherein a portion of said metal conduit respectively connected to said exit and said entrance of said housing is made of polymer material or other thermal insulating material to avoid reversed thermal diffusion.

17. The screen module of claim 11, wherein the closed-loop heat-dissipation cycle is realized by using said metal conduit to transport the air from said housing and dissipate heat carried with the air while without thermal convection between the air within said housing and atmosphere.

18. The screen module of claim 11, wherein a fan is disposed at surrounding of said housing.

19. The screen module of claim 11, wherein an outer surface of said housing is provided with a plurality of heat-dissipation fins.

20. The screen module of claim 11, wherein said exit is positioned at an upper portion of said housing, and said entrance is positioned at a lower portion of said housing.

21. The screen module of claim 11, wherein said heat bodies are lamp tube module.
